(19) United States
(12) Patent Application Publication
(10) Pub. No.: US 2020/0187359 A1
(43) Pub. Date: Jun. 11, 2020

(54) FLEXIBLE SUBSTRATE AND FLEXIBLE PANEL

(71) Applicant: WUHAN CHINA STAR OPTOELECTRONICS TECHNOLOGY CO., LTD., Wuhan, Hubei (CN)

(72) Inventor: Yingbo ZHENG, Wuhan, Hubei (CN)

(21) Appl. No.: 16/476,305

(22) PCT Filed: Mar. 6, 2019
(86) PCT No.: PCT/CN2019/077137

§ 371 Date: Jul. 8, 2019

(30) Foreign Application Priority Data
Jul. 24, 2018 (CN) 201810820377.X

(51) Int. Cl. H05K 1/18; H05K 1/11

(52) U.S. Cl. CPC H05K 1/189; H05K 2201/10984; H05K 2201/10128; H05K 1/11

(57) ABSTRACT

A flexible substrate and a display panel are provided and include a substrate and a flexible circuit board disposed on the substrate. The flexible circuit board includes a plurality of pin sections arranged in a predetermined direction, wherein a plurality of metal pins are disposed on the pin sections, and a groove is defined between the adjacent pin sections so as to prevent the metal pins from being misaligned when the flexible circuit board is aligned with the substrate.

### FIELD OF INVENTION

The present application relates to the field of display technologies, and more particularly, to a flexible substrate and a flexible panel.

### BACKGROUND OF INVENTION

Existing display modules on the market include display substrates, driver chips, and flexible printed circuits (FPCs), which are widely used in mobile phones, tablet computers, and liquid crystal displays.

When an existing display substrate is bonded to an FPC, an input pad of the display substrate is electrically connected to an output pad of the FPC by an anisotropic conductive film. However, material of the FPC is a polyimide film which has a large expansion coefficient and material of the display substrate is generally a borosilicate glass. In the case of high temperature, there is a thermal expansion coefficient difference between the FPC and the display substrate, thereby causing the FPC to not be accurately aligned with a position of the display substrate. Thus, this reduces product yield.

### Technical Problems

The technical problems mainly solved by the present application are how to improve the accuracy of the alignment between the FPC and the substrate, thereby increasing a yield product.

### SUMMARY OF INVENTION

In a first aspect, the present application provides a flexible substrate, comprising:

a substrate and a flexible circuit board disposed on the substrate;

wherein the flexible circuit board comprises a plurality of pin sections arranged in a predetermined direction, a plurality of metal pins are disposed on the pin sections, and a groove is defined between the adjacent pin sections to prevent the metal pins from being misaligned when the flexible circuit board is aligned with the substrate;

wherein the substrate comprises a support surface, an adhesive layer is disposed on the support surface, the flexible circuit board is bonded to the substrate through the adhesive layer, and the metal pins is electrically connected to the substrate through the adhesive layer; and

wherein material of the adhesive layer is an anisotropic conductive adhesive.

In the flexible substrate provided by the present application, each of the pin section comprises a first section, a second section, and a third section arranged in the predetermined direction, the groove comprises a first groove and a second groove; and wherein the first groove is defined between the first section and the second section, and the second groove is defined between the second section and the third section.

In the flexible substrate provided by the present application, a length of the first section is greater than a length of the second section, and the length of the second section is greater than a length of the third section; and wherein a cross-sectional area of the first groove is greater than a cross-sectional area of the second groove.

In the flexible substrate provided by the present application, a length of the first section, a length of the second section, and a length of the third section are all equal.

In the flexible substrate provided by the present application, the length of the first section is between 0 and 70 millimeters.

In the flexible substrate provided by the present application, a depth of the groove is greater than lengths of the metal pins.

In the flexible substrate provided by the present application, wherein the substrate comprises a plurality of protrusions, the protrusions are in one-to-one correspondence with the grooves, and a cross-sectional area of the groove is greater than cross-sectional areas of the protrusions.

In a second aspect, the present application provides a flexible substrate, comprising:

a substrate and a flexible circuit board disposed on the substrate;

wherein the flexible circuit board comprises a plurality of pin sections arranged in a predetermined direction, a plurality of metal pins are disposed on the pin sections, and a groove is defined between the adjacent pin sections to prevent the metal pins from being misaligned when the flexible circuit board is aligned with the substrate.

In the flexible substrate provided by the present application, each of the pin section comprises a first section, a second section, and a third section arranged in the predetermined direction, the groove comprises a first groove and a second groove; and wherein the first groove is defined between the first section and the second section, and the second groove is defined between the second section and the third section.

In the flexible substrate provided by the present application, a length of the first section is greater than a length of the second section, and the length of the second section is greater than a length of the third section; and wherein a cross-sectional area of the first groove is greater than a cross-sectional area of the second groove.

In the flexible substrate provided by the present application, a length of the first section, a length of the second section, and a length of the third section are all equal.

In the flexible substrate provided by the present application, the length of the first section is between 0 and 70 millimeters.

In the flexible substrate provided by the present application, a depth of the groove is greater than lengths of the metal pins.

In the flexible substrate provided by the present application, the substrate comprises a plurality of protrusions, the protrusions are in one-to-one correspondence with the grooves, and a cross-sectional area of the groove is greater than cross-sectional areas of the protrusions.

In the flexible substrate provided by the present application, the substrate comprises a support surface, an adhesive layer is disposed on the support surface, the flexible circuit board is bonded to the substrate through the adhesive layer, and the metal pins is electrically connected to the substrate through the adhesive layer.

In the flexible substrate provided by the present application, material of the substrate is borosilicate glass.

In the flexible substrate provided by the present application, the material of the substrate is borosilicate glass.

In a third aspect, the present application provides a flexible panel, comprising a flexible substrate;

wherein the flexible substrate comprises:

a substrate and a flexible circuit board disposed on the substrate;

wherein the flexible circuit board comprises a plurality of pin sections arranged in a predetermined direction, a plurality of metal pins are disposed on the pin sections, and a groove is defined between the adjacent pin sections to prevent the metal pins from being misaligned when the flexible circuit board is aligned with the substrate.

In the flexible panel provided by the present application, each of the pin section comprises a first section, a second section, and a third section arranged in the predetermined direction, the groove comprises a first groove and a second groove; and wherein the first groove is defined between the first section and the second section, and the second groove is defined between the second section and the third section.

In the flexible panel provided by the present application, a length of the first section is greater than a length of the second section, and the length of the second section is greater than a length of the third section; and wherein a cross-sectional area of the first groove is greater than a cross-sectional area of the second groove.

### Beneficial Effects

The beneficial effects of the present application are to prevent metal pins from being misaligned when a flexible circuit board is aligned with a substrate by providing a groove between adjacent pin sections. Therefore, the accuracy of the alignment between the flexible circuit board and the substrate is increased, thereby increasing a product yield.

### DESCRIPTION OF DRAWINGS

In order to illustrate technical solutions in the embodiments of the present application more clearly, the accompanying drawings required in the description of the embodiments are introduced hereafter.

FIG. 1 is a schematic plan view of a flexible substrate provided by a first embodiment of the present application;

FIG. 2 is a schematic structural view of the flexible substrate provided by the first embodiment of the present application;

FIG. 3 is a schematic plan view showing the flexible substrate provided by a second embodiment of the present application; and

FIG. 4 is a schematic plan view of the flexible substrate provided by a third embodiment of the present application.

### DETAILED DESCRIPTION OF PREFERRED EMBODIMENTS

Embodiments of the present application will be described in detail in the following descriptions, examples of which are shown in the accompanying drawings, in which the same or similar reference numerals represent the same or similar elements or elements having the same or similar functions throughout the descriptions. The embodiments described hereinafter with reference to the accompanying drawings are explanatory and illustrative, which are used to generally understand the present application, but shall not be construed to limit the present application.

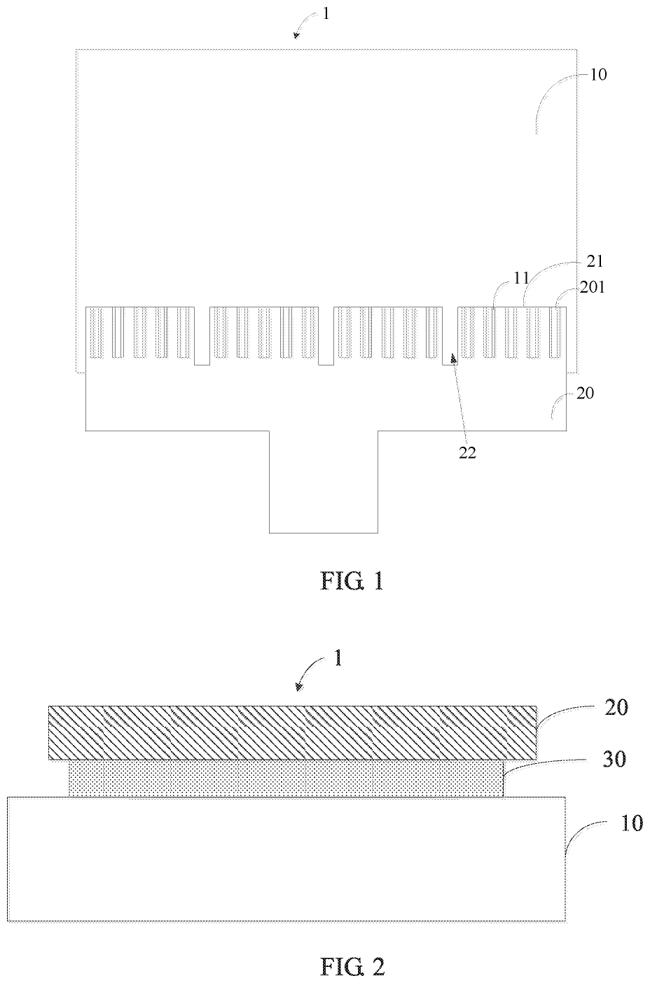

Please refer to FIG. 1, which is a schematic plan view of a flexible substrate provided by a first embodiment of the present application.

The present application provides a flexible substrate 1, comprising: a substrate 10 and a flexible circuit board 20 disposed on the substrate 10. The flexible circuit board 20 comprises a plurality of pin sections 21 arranged in a predetermined direction. A plurality of metal pins 201 are disposed on each of the pin sections 21, and a groove 22 is disposed between the adjacent pin sections 21.

For example, material of the substrate 10 may be borosilicate glass and the substrate 10 may be provided with a plurality of driver chips 11 which are in one-to-one correspondence with the metal pins 201.

Referring to FIG. 1 and FIG. 2, the substrate 10 comprises a supporting surface on which an adhesive layer 30 is disposed. The adhesive layer 30 may be an anisotropic conductive adhesive. The flexible circuit board 20 is bonded to the substrate 10 via the adhesive layer 30 and the metal pins 201 are electrically connected to the substrate 10 via the adhesive layer 30, i.e., the metal pins 201 is electrically connected to the driver chips 11 via the adhesive layer 30. In the pressing process, a plurality of metal pins 201 can be pressed onto the driver chips 11 by heat-press by a pressing device. The pressing device is controlled to heat the anisotropic conductive adhesive 30 of the substrate 10 during the pressing process so that a resin layer of the anisotropic conductive paste 30 undergoes a reaction. At the same time, the pressing device is controlled to downwardly press the flexible circuit board 20, so that conductive particles of the anisotropic conductive paste 30 form a conductive path between the metal pins 201 and the driver chip 11 to complete the bonding of the flexible circuit board 20 and the substrate 10.

It should be noted that, in the case of high temperature, a thermal expansion coefficient difference between the flexible circuit board 20 and the substrate 10 is existed, thereby causing the FPC to not be accurately aligned with a position of the display substrate. Therefore, a groove 22 is defined between the adjacent pin sections 21 to prevent the metal pins 201 from being misaligned and short-circuited when the flexible circuit board 20 is aligned with the substrate 10. Therefore, the accuracy of the alignment between the FPC and the substrate is increased, thereby increasing the product yield. A depth of the groove 22 is greater than lengths of the metal pins 201.

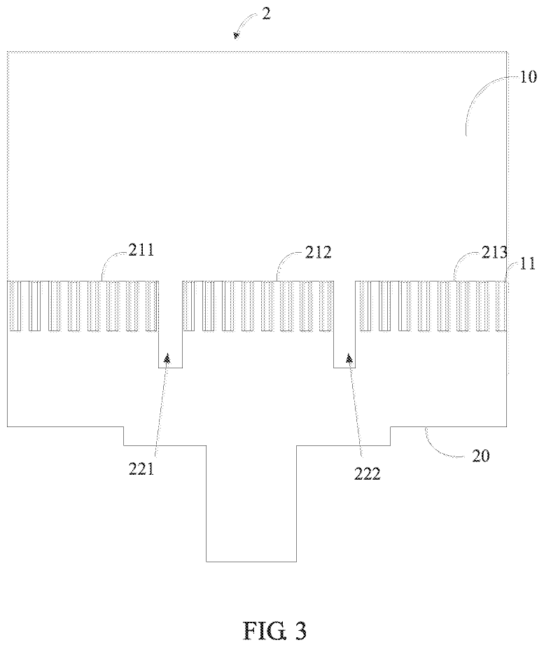

Please refer to FIG. 3, which is a schematic plan view of the flexible substrate provided by a second embodiment of the present application.

The pin section 21 comprises a first section 211, a second section 212, and a third section 213 arranged in a predetermined direction, and the groove 22 comprises a first groove 221 and a second groove 222. The first groove 221 is defined between the first section 211 and the second section 212, and the second groove 222 is disposed between the second section 212 and the third section 213.

The predetermined direction may be a horizontal direction, i.e., the first section 211, the second section 212, and the third section 213 are arranged on the flexible circuit board 20 in a horizontal direction. A cross-sectional area of the first groove 221 and a cross-sectional area of the second groove 222 is specifically set according to a length of the first section 211, a length of the second section 212, and a length of the third section 213.

For example, the length of the first section 211, the length of the second section 212, and the length of the third section 213 are all equal, and the cross-sectional area of the first groove 221 is equal to the cross-sectional area of the second groove 222.

Further, for example, the length of the first section 211 is greater than the length of the second section 212, and the length of the second section 212 is greater than a length of the third section 213. The cross-sectional area of the first groove 221 is greater than the cross-sectional area of the second groove 222.

It should be noted that the total number of pins that can be accommodated in one single pin section 21 is affected by the process limitations during binding. Therefore, a single pin section 21 cannot exceed 70 mm; otherwise, a short-circuit may occur due to the misalignment of the driver chip 11 after expansion. i.e., the length of one single pin section 21 is between 0 and 70 mm, that is, the length of the first section 211, the length of the second section 212, and the length of the third section 213 are between 0 and 70 mm.

In the present embodiment, by providing a groove 22 between adjacent pin sections 21, the metal pin 201 is prevented from being misaligned and short-circuited when the flexible circuit board 20 is aligned with the substrate 10. Therefore, the accuracy of alignment between the flexible circuit board 20 and the substrate 10 is increased, thereby increasing a product yield. At the same time, the groove 22 defined between adjacent pin sections 21 can also widen the binding area of the flexible circuit board 20, thereby providing support on signal input for increasing resolution of a liquid crystal panel.

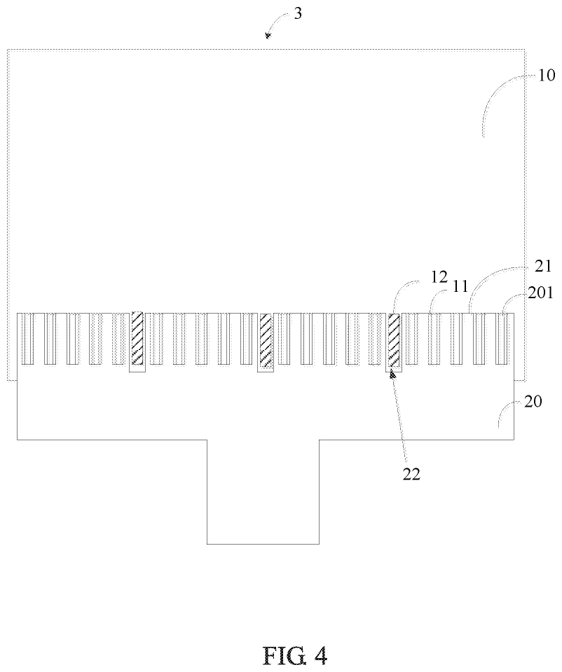

Please refer to FIG. 4, which is a schematic plan view showing a third embodiment of the flexible substrate provided by the present application. The substrate 10 comprises a plurality of protrusions 12. The protrusions 12 are in one-to-one correspondence with the grooves 22 and the cross-sectional areas of the grooves 22 is greater than cross-sectional areas of the protrusions 12.

For example, the protrusion 12 is accommodated in the groove 22 and the protrusion 12 has a certain interval from the side wall of the groove 22. A thickness of the protrusions 12 is equal to a thickness of the flexible circuit board 20. When the flexible circuit board 20 is aligned with the substrate 10, the heat of the pins 201 in each of the pin sections 21 is expanded. Because the protrusion 12 are accommodated in the groove 22, the adjacent pin sections 21 do not affect each other even if they are expanded by heat. Therefore, the product yield is further increased.

Correspondingly, the present application also provides a flexible panel, comprising any of the flexible substrates of the above embodiments. Please refer to the previous embodiments, and details are not described herein again.

In the present embodiment, by providing a groove 22 between adjacent pin sections 21, the metal pins 201 are prevented from being misaligned when the flexible circuit board 20 is aligned with the substrate 10. Therefore, the accuracy of the alignment of the flexible circuit board 20 with the substrate 10 can be increased, thereby increasing the product yield. At the same time, a plurality of protrusions 12 are provided on the substrate 10, and the protrusions 12 are in one-to-one correspondence with the grooves 22. The adjacent pin sections 21 do not affect each other even if they are expanded by heat. Therefore, the product yield is further increased.

The flexible substrate and the flexible panel provided by the present application are described in detail hereabove. Specific examples are used herein to describe the principle and implementations of the present application. The descriptions of the foregoing embodiments are merely for understanding the present application. In addition, with respect to the implementations and the application scope, modifications may be made by a person of ordinary skill in the art according to the idea of the present application. Therefore, this specification shall not be construed as a limitation on the present application.

1. A flexible substrate, comprising:
a substrate and a flexible circuit board disposed on the substrate;
wherein the flexible circuit board comprises a plurality of pin sections arranged in a predetermined direction, a plurality of metal pins are disposed on the pin sections, and grooves are defined between the adjacent pin sections to prevent the metal pins from being misaligned when the flexible circuit board is aligned with the substrate;
wherein the substrate comprises a support surface, an adhesive layer is disposed on the support surface, the flexible circuit board is bonded to the substrate through the adhesive layer, and the metal pins is electrically connected to the substrate through the adhesive layer; and
wherein material of the adhesive layer is an anisotropic conductive adhesive.

2. The flexible substrate according to claim 1, wherein each of the pin section comprises a first section, a second section, and a third section arranged in the predetermined direction, the grooves comprises a first groove and a second groove; and wherein the first groove is defined between the first section and the second section, and the second groove is defined between the second section and the third section.

3. The flexible substrate according to claim 2, wherein a length of the first section is greater than a length of the second section, and the length of the second section is greater than a length of the third section; and wherein a cross-sectional area of the first groove is greater than a cross-sectional area of the second groove.

4. The flexible substrate according to claim 2, wherein a length of the first section, a length of the second section, and a length of the third section are all equal.

5. The flexible substrate according to claim 4, wherein the length of the first section is between 0 and 70 millimeters.

6. The flexible substrate according to claim 1, wherein a depth of the groove is greater than lengths of the metal pins.

7. The flexible substrate according to claim 6, wherein the substrate comprises a plurality of protrusions, the protrusions are in one-to-one correspondence with the grooves, and a cross-sectional area of the groove is greater than cross-sectional areas of the protrusions.

8. A flexible substrate comprising:
a substrate and a flexible circuit board disposed on the substrate;
wherein the flexible circuit board comprises a plurality of pin sections arranged in a predetermined direction, a plurality of metal pins are disposed on the pin sections, and grooves are defined between the adjacent pin sections to prevent the metal pins from being misaligned when the flexible circuit board is aligned with the substrate.

9. The flexible substrate according to claim 8, wherein each of the pin section comprises a first section, a second section, and a third section arranged in the predetermined direction, the grooves comprises a first groove and a second groove; and wherein the first groove is defined between the first section and the second section, and the second groove is defined between the second section and the third section.

10. The flexible substrate according to claim 9, wherein a length of the first section is greater than a length of the second section, and the length of the second section is greater than a length of the third section; and wherein a cross-sectional area of the first groove is greater than a cross-sectional area of the second groove.

11. The flexible substrate according to claim 9, wherein a length of the first section, a length of the second section, and a length of the third section are all equal.

12. The flexible substrate according to claim 11, wherein the length of the first section is between 0 and 70 millimeters.

13. The flexible substrate according to claim 8, wherein a depth of the groove is greater than lengths of the metal pins.

14. The flexible substrate according to claim 13, wherein the substrate comprises a plurality of protrusions, the protrusions are in one-to-one correspondence with the grooves, and a cross-sectional area of the groove is greater than cross-sectional areas of the protrusions.

15. The flexible substrate according to claim 8, wherein the substrate comprises a support surface, an adhesive layer is disposed on the support surface, the flexible circuit board is bonded to the substrate through the adhesive layer, and the metal pins is electrically connected to the substrate through the adhesive layer.

16. The flexible substrate according to claim 15, wherein material of the adhesive layer is an anisotropic conductive adhesive.

17. The flexible substrate according to claim 8, wherein material of the substrate is borosilicate glass.

18. A flexible panel, comprising a flexible substrate;
wherein the flexible substrate comprises:
a substrate and a flexible circuit board disposed on the substrate;
wherein the flexible circuit board comprises a plurality of pin sections arranged in a predetermined direction, a plurality of metal pins are disposed on the pin sections, and grooves are defined between the adjacent pin sections to prevent the metal pins from being misaligned when the flexible circuit board is aligned with the substrate.

19. The flexible panel according to claim 18, wherein each of the pin section comprises a first section, a second section, and a third section arranged in the predetermined direction, the grooves comprises a first groove and a second groove; and wherein the first groove is defined between the first section and the second section, and the second groove is defined between the second section and the third section.

20. The flexible panel according to claim 19, wherein a length of the first section is greater than a length of the second section, and the length of the second section is greater than a length of the third section; and wherein a cross-sectional area of the first groove is greater than a cross-sectional area of the second groove.
